(19) United States
(12) Patent Application Publication
(10) Pub. No.: US 2026/0353792 A1
(43) Pub. Date: Nov. 5, 2026

(54) COMPLEMENTARY FIELD-EFFECT TRANSISTOR DEVICES AND METHODS OF FORMING

(71) Applicant: Taiwan Semiconductor Manufacturing Co., Ltd., Hsinchu (TW)

(72) Inventors: Wei-De Ho, Hsinchu (TW); Wei-Xiang You, Kaohsiung City (TW)

(21) Appl. No.: 19/736,342

(22) Filed: Jul. 9, 2026

Related U.S. Application Data
(63) Continuation of application No. 19/025,339, filed on Jan. 16, 2025.
(60) Provisional application No. 63/699,669, filed on Sep. 26, 2024.

(51) Int. Cl. H10D 84/85; H10D 30/00; H10D 30/01; H10D 30/43; H10D 62/10; H10D 62/13; H10D 84/01; H10W 72/00; H10W 80/00; H10W 90/00

(52) U.S. Cl. CPC H10D 84/856; H10D 30/014; H10D 30/0191; H10D 30/43; H10D 30/502; H10D 62/121; H10D 62/151; H10D 84/017; H10D 84/851; H10W 72/0198; H10W 80/312; H10W 80/327; H10W 90/792

(57) ABSTRACT

A semiconductor device includes: a first substrate; a first fin protruding above the first substrate; first nanostructures over the first fin; a first gate structure around the first nanostructures; a first source/drain region adjacent to the first gate structure and contacting a first subset of the first nanostructures; a first dielectric structure between the first source/drain region and the first fin, where the first dielectric structure contacts a second subset of the first nanostructures; second nanostructures over the first fin and laterally spaced apart from the first nanostructures; a second gate structure around the second nanostructures; and a second source/drain region adjacent to the second gate structure and contacting the second nanostructures.

### PRIORITY CLAIM AND CROSS-REFERENCE

This application is a continuation of U.S. Patent Application No 19/025,339, filed Jan. 16, 2025 and entitled “Complementary Field-Effect Transistor Devices and Methods of Forming,” which claims priority to U.S. Provisional Patent Application No. 63/699,669, filed Sep. 26, 2024 and entitled “Parallel CFET with Multi/Hybrid Nanosheet,” which applications are hereby incorporated by reference in their entireties.

### BACKGROUND

Semiconductor devices are used in a variety of electronic applications, such as, for example, personal computers, cell phones, digital cameras, and other electronic equipment. Semiconductor devices are typically fabricated by depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

Recently, vertically stacked transistor devices, such as complementary field-effect transistor (CFET) devices, provides a promising new architecture that achieves improved integration density by forming nanostructure field-effect transistors (NSFETs) that are vertically stacked over a substrate. Various aspects of this new architecture need to be studied and improved to achieve better device performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (NSFET) device in a three-dimensional view, in accordance with some embodiments.

FIGS. 2, 3A, 3B, 4A, 4B, 5A, 5B, 5C, 6A, 6B, 6C, 7A, 7B, 7C, 8A, 8B, 8C, 8D, 9A, 9B, 9C, 9D, 10A, 10B, 11A, 11B, 12A, 12B, 13A, 13B, 14, 15A, and 15B are cross-sectional views of a complementary field-effect transistor (CFET) device at various stages of manufacturing, in accordance with an embodiment.

FIG. 16 illustrates a cross-sectional view of a CFET device, in accordance with another embodiment.

FIG. 17 illustrates a cross-sectional view of a CFET device, in accordance with another embodiment.

FIG. 18 illustrates a cross-sectional view of a CFET device, in accordance with another embodiment.

FIG. 19 illustrates a cross-sectional view of a CFET device, in accordance with yet another embodiment.

FIG. 20 illustrates a flow chart of a method of forming a semiconductor device, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

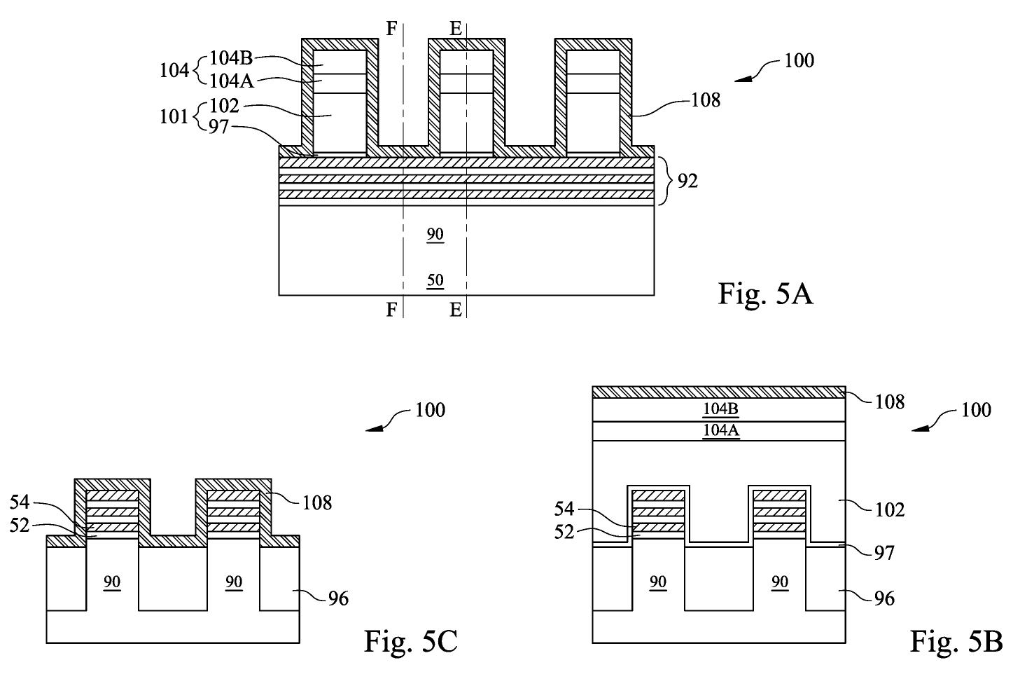

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Throughout the discussion herein, unless otherwise described, the same or similar reference numeral in different figures refer to the same or similar component formed by a same or similar formation process using a same or similar material(s). In addition, figures with the same numeral but different alphabets (e.g., FIGS. 5A-5C) illustrate different views of the same device at the same stage of processing.

In accordance with some embodiments, a first NSFET device comprising a first type (e.g., N-type) of NSFETs is formed over a first substrate (e.g., a first wafer), and a first interconnect structure is formed over the NSFETs at the front-side of the first substrate. A second NSFET device comprising a second type (e.g., P-type) of NSFETs is formed over a second substrate (e.g., a second wafer), and a second interconnect structure is formed over the NSFETs at the front-side of the second substrate. The NSFETs of the first NSFET device (or the second NSFET device) may have different numbers of active nanostructures in different regions of the first NSFET device (or the second NSFET device). The different numbers of active nanostructures of the NSFETs are achieved by forming dielectric structures of different heights in the source/drain openings before forming the source/drain regions. The first interconnect structure of the first NSFET device is bonded to the second interconnect structure of the second NSFET device to form a CFET device with vertically stacked NSFETs.

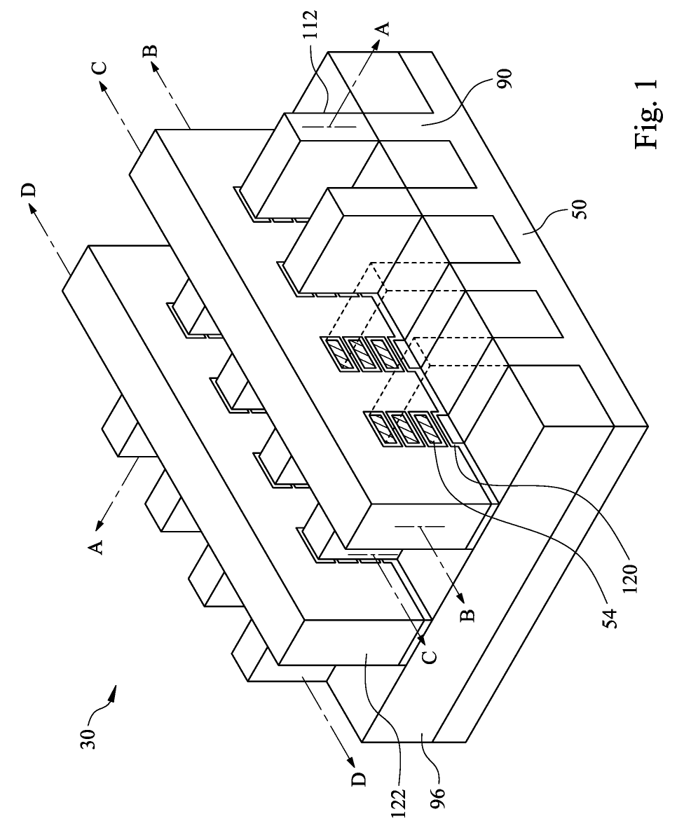

FIG. 1 illustrates an example of a nanostructure field-effect transistor (NSFET) device 30 in a three-dimensional view, in accordance with some embodiments. The NSFET device 30 comprises semiconductor fins 90 (also referred to as fins) protruding above a substrate 50. Gate electrodes 122 (e.g., metal gates) are disposed over the fins, and source/drain regions 112 are formed on opposing sides of the gate electrodes 122. A plurality of nanostructures 54 (e.g., nanowires, or nanosheets) are formed over the fins 90 and between source/drain regions 112. Isolation regions 96 are formed on opposing sides of the fins 90. A gate dielectric layer 120 is formed around the nanostructures 54. Gate electrodes 122 are over and around the gate dielectric layer 120.

FIG. 1 further illustrates reference cross-sections that are used in later figures. Cross-section A-A is along a longitudinal axis of the fin 90 and is in a direction of, for example, a current flow between the source/drain regions 112 of the NSFET device. Cross-section B-B is perpendicular to cross-section A-A and is along a longitudinal axis of the gate electrode 122. Cross-section C-C is parallel to cross-section B-B and extends through source/drain regions 112 of the NSFET device. Cross-section D-D is parallel to cross-section C-C and extends through other source/drain regions 112 of the NSFET device. Subsequent figures may refer to these reference cross-sections for clarity.

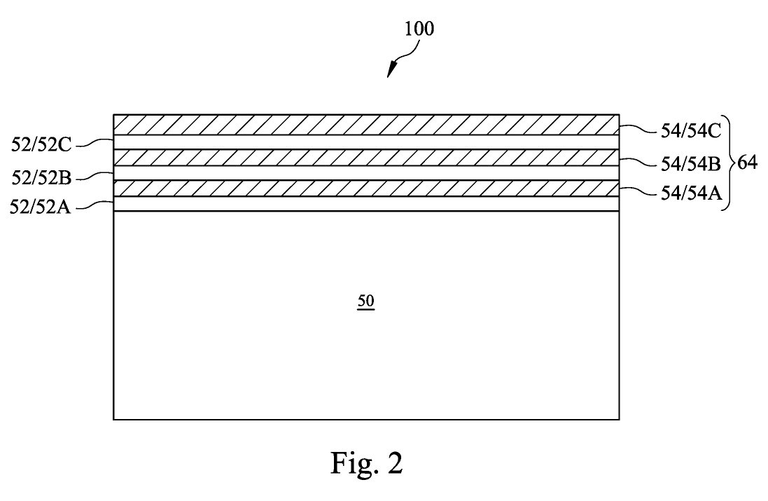

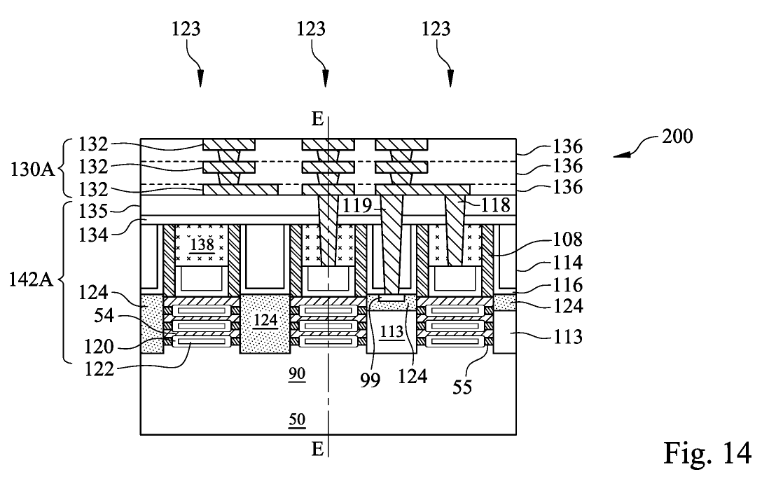

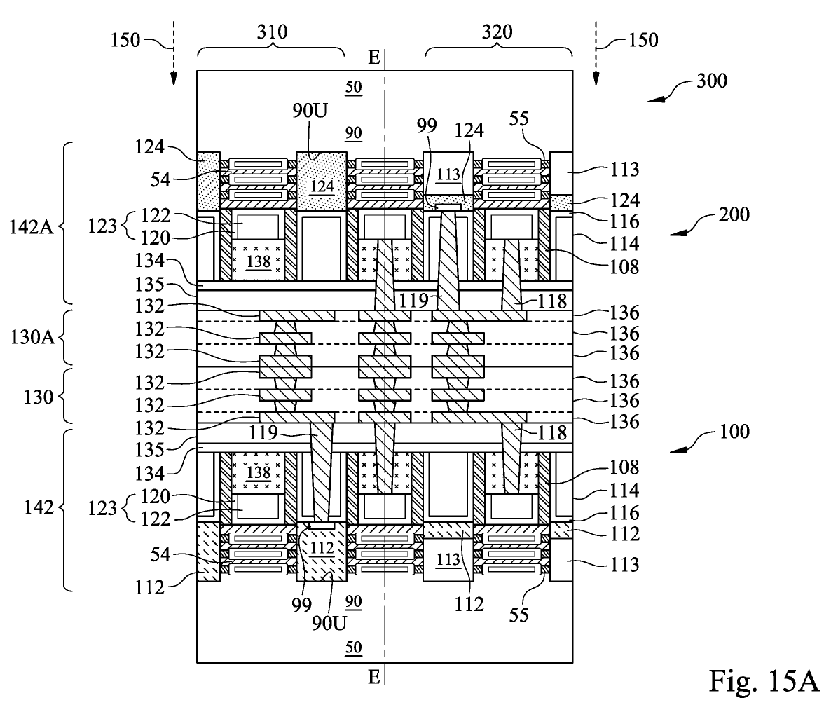

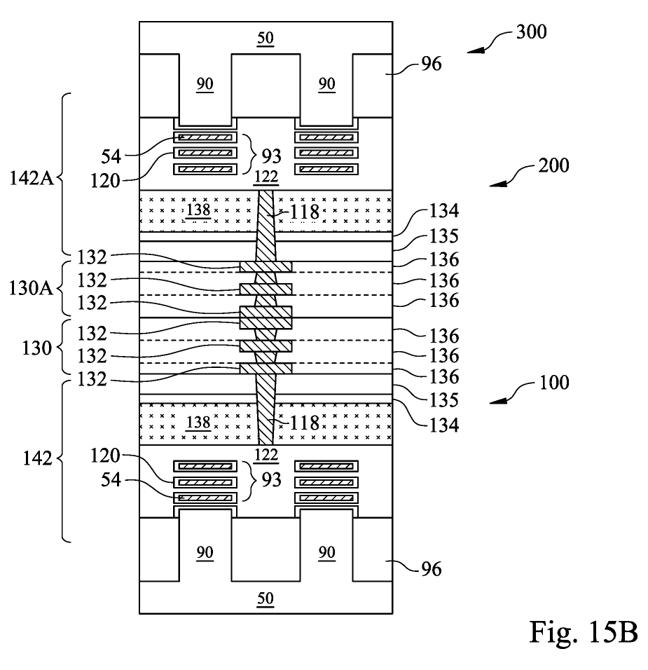

FIGS. 2, 3A, 3B, 4A, 4B, 5A, 5B, 5C, 6A, 6B, 6C, 7A, 7B, 7C, 8A, 8B, 8C, 8D, 9A, 9B, 9C, 9D, 10A, 10B, 11A, 11B, 12A, 12B, 13A, 13B, 14, 15A, and 15B are cross-sectional views of a complementary field-effect transistor (CFET) device 300 at various stages of manufacturing, in accordance with an embodiment. In particular, FIGS. 2, 3A, 3B, 4A, 4B, 5A, 5B, 5C, 6A, 6B, 6C, 7A, 7B, 7C, 8A, 8B, 8C, 8D, 9A, 9B, 9C, 9D, 10A, 10B, 11A, 11B, 12A, 12B, 13A, and 13B illustrate cross-sectional views of an NSFET device 100 at various stages of processing, in an embodiment. FIG. 14 illustrates a cross-sectional view of an NSFET device 200, in an embodiment. The NSFET device 100 and the NSFET device 200 are bonded together to form the CFET device 300, as illustrated by the cross-sectional views of FIGS. 15A and 15B.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon substrate or a glass substrate. Other substrates, such as a multi-layered or gradient substrate may also be used. In some embodiments, the semiconductor material of the substrate 50 includes silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

A multi-layer stack 64 is formed on the substrate 50. The multi-layer stack 64 includes alternating layers of a first semiconductor material 52 and a second semiconductor material 54. In FIG. 2, layers formed by the first semiconductor material 52 are labeled as 52A, 52B, and 52C, and layers formed by the second semiconductor material 54 are labeled as 54A, 54B, and 54C. The number of layers formed by the first and the second semiconductor materials illustrated in FIG. 2 are merely non-limiting examples. Other numbers of layers are also possible and are fully intended to be included within the scope of the present disclosure.

In some embodiments, the first semiconductor material 52 is an epitaxial material appropriate for forming channel regions of p-type FETs, such as silicon germanium (SiₓGe₁₋ₓ, where x can be in the range of 0 to 1), and the second semiconductor material 54 is an epitaxial material appropriate for forming channel regions of n-type FETs, such as silicon. In some embodiments, the second semiconductor material 54 (e.g., silicon) may be used to form both n-type or p-type FETs, and the first semiconductor material 52 is used as a sacrificial material that is removed later. The multi-layer stack 64 (which may also be referred to as an epitaxial material stack) will be patterned to form channel regions of an NSFET in subsequent processing. For example, the multi-layer stack 64 may be patterned and etched to form nanostructures (e.g., nanosheets or nanowires), with the channel regions of the resulting NSFET including nanostructures that are vertically stacked over a fin, and with each nanostructure extending parallel to a major upper surface of the substrate.

The multi-layer stack 64 may be formed by an epitaxial growth process, which may be performed in a growth chamber. During the epitaxial growth process, the growth chamber is cyclically exposed to a first set of precursors for selectively growing the first semiconductor material 52, and then exposed to a second set of precursors for selectively growing the second semiconductor material 54, in some embodiments. The first set of precursors includes precursors for the first semiconductor material (e.g., silicon germanium), and the second set of precursors includes precursors for the second semiconductor material (e.g., silicon). In some embodiments, the first set of precursors includes a silicon precursor (e.g., silane) and a germanium precursor (e.g., a germane), and the second set of precursors includes the silicon precursor but omits the germanium precursor. The epitaxial growth process may thus include continuously enabling a flow of the silicon precursor to the growth chamber, and then cyclically: (1) enabling a flow of the germanium precursor to the growth chamber when growing the first semiconductor material 52; and (2) disabling the flow of the germanium precursor to the growth chamber when growing the second semiconductor material 54. The cyclical exposure may be repeated until a target number of layers is formed.

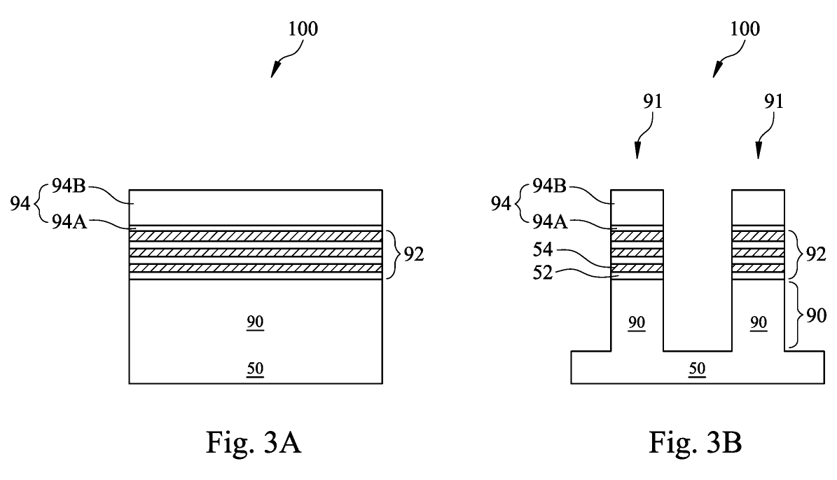

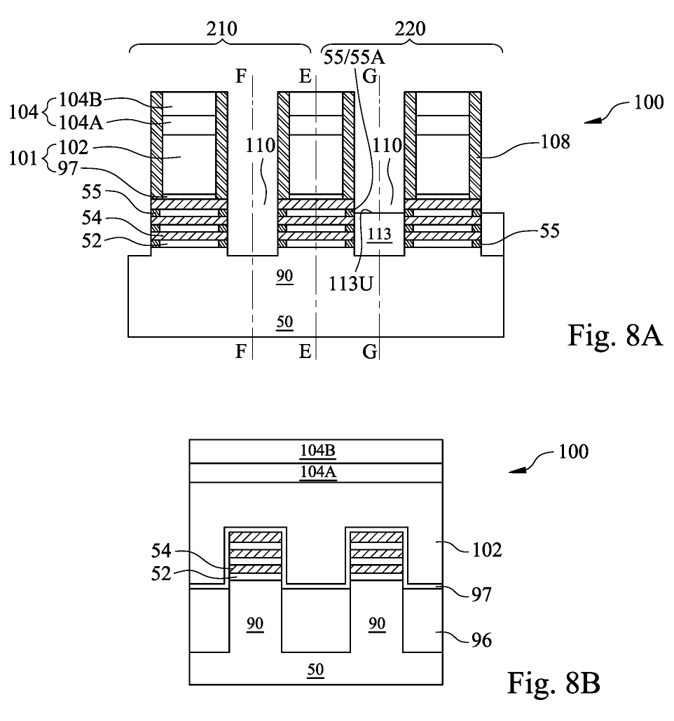

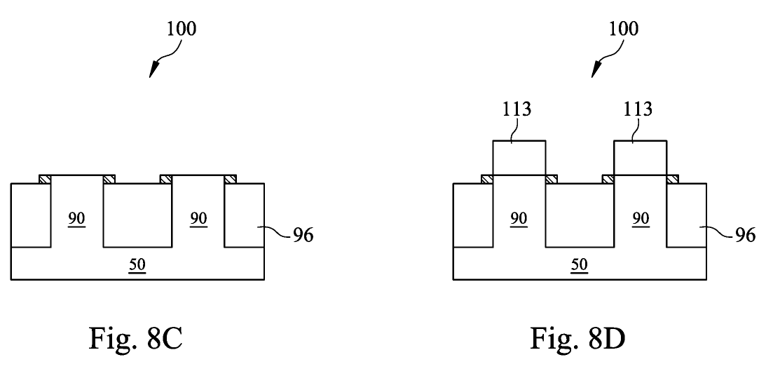

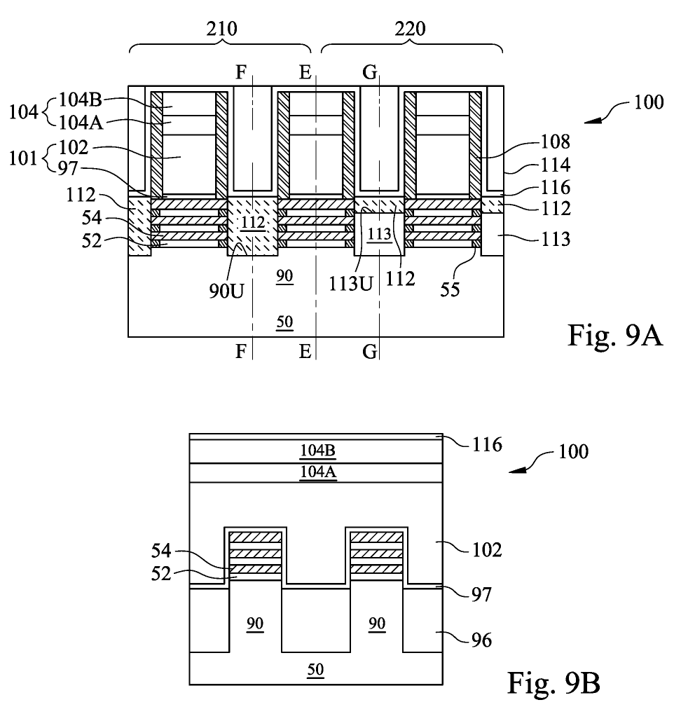

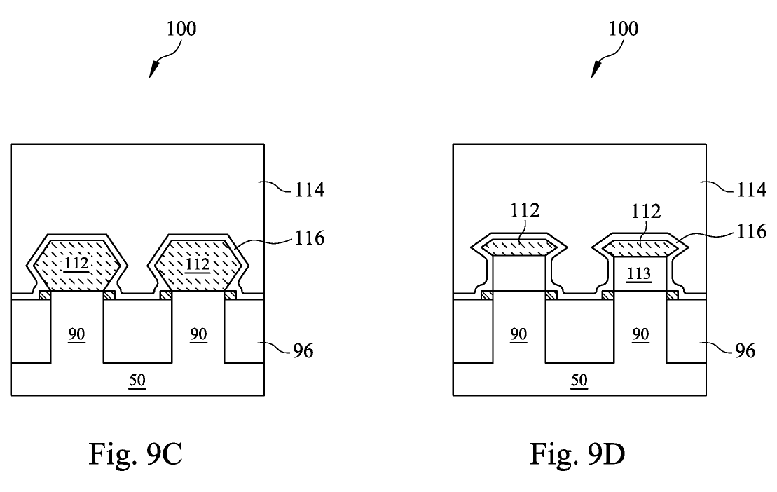

FIGS. 3A, 3B, 4A, 4B, 5A, 5B, 5C, 6A, 6B, 6C, 7A, 7B, 7C, 8A, 8B, 8C, 8D, 9A, 9B, 9C, 9D, 10A, 10B, 11A, 11B, 12A, 12B, 13A, and 13B are cross-sectional views of the NSFET device 100 at subsequent stages of manufacturing, in accordance with an embodiment. FIGS. 3A, 4A, 5A, 6A, 7A, 8A, 9A, 10A, 11A, 12A, and 13A are cross-sectional views along cross-section A-A in FIG. 1. FIGS. 3B, 4B, 5B, 6B, 7B, 8B, 9B, 10B, 11B, 12B, and 13B are cross-sectional views along cross-section B-B in FIG. 1. FIGS. 5C, 6C, 7C, 8C, and 9C are cross-sectional views along cross-section C-C in FIG. 1. FIGS. 8D and 9D are cross-sectional views along cross-section D-D in FIG. 1. The number of fins and the number of gate structures illustrated in the figures are merely non-limiting examples, it should be appreciated that other numbers of fins and other numbers of gate structures may also be formed.

In FIG. 3A and 3B, fin structures 91 are formed protruding above the substrate 50. Each of the fin structures 91 includes a semiconductor fin 90 (also referred to as a fin) and a layer stack 92 overlying the semiconductor fin 90. The layer stack 92 and the semiconductor fin 90 may be formed by etching trenches in the multi-layer stack 64 and the substrate 50, respectively. The layer stack 92 and the semiconductor fin 90 may be formed by a same etching process.

The fin structures 91 may be patterned by any suitable method. For example, the fin structures 91 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. In an embodiment, a sacrificial layer is formed over a substrate and patterned using a photolithography process. Spacers are formed alongside the patterned sacrificial layer using a self-aligned process. The sacrificial layer is then removed, and the remaining spacers are then be used to pattern, e.g., the fin structures 91.

In some embodiments, the remaining spacers are used to pattern a mask 94, which is then used to pattern the fin structures 91. The mask 94 may be a single layer mask, or may be a multilayer mask such as a multilayer mask that includes a first mask layer 94A and a second mask layer 94B. The first mask layer 94A and second mask layer 94B may each be formed from a dielectric material such as silicon oxide, silicon nitride, a combination thereof, or the like, and may be deposited or thermally grown according to suitable techniques. The first mask layer 94A and second mask layer 94B are different materials having a high etching selectivity. For example, the first mask layer 94A may be silicon oxide, and the second mask layer 94B may be silicon nitride. The mask 94 may be formed by patterning the first mask layer 94A and the second mask layer 94B using any acceptable etching process. The mask 94 may then be used as an etching mask to etch the substrate 50 and the multi-layer stack 64. The etching may be any acceptable etch process, such as a reactive ion etch (RIE), neutral beam etch (NBE), the like, or a combination thereof. The etching is an anisotropic etching process, in some embodiments. After the etching process, the patterned multi-layer stack 64 forms the layer stacks 92, and the patterned portion of the substrate 50 forms the fins 90, as illustrated in FIG. 3A and 3B. The unetched lower portion of the substrate 50 is referred to as substrate 50 in FIGS. 3A and 3B (and subsequent figures). Therefore, in the illustrated embodiment, the layer stack 92 also includes alternating layers of the first semiconductor material 52 and the second semiconductor material 54, and the fin 90 is formed of a same material (e.g., silicon) as the substrate 50.

The fins 90 and the layer stacks 92 in FIG. 3B are illustrated to have substantially perpendicular sidewalls (e.g. perpendicular to the major upper surface of the substrate 50). The shapes of the fins 90 and the layer stacks 92 illustrated in FIG. 3B are merely non-limiting examples. The fins 90 and the layer stacks 92 may have sloped sidewalls (e.g., having trapezoidal cross-sections). The sloped sidewalls may be formed due to the properties of the anisotropic etching process used to form the fins 90 and the layer stacks 92. For example, the etching capability of the anisotropic etching process may decrease along the downward vertical direction of FIG. 3B, which may result in the sloped sidewalls for the fins 90 and the layer stacks 92.

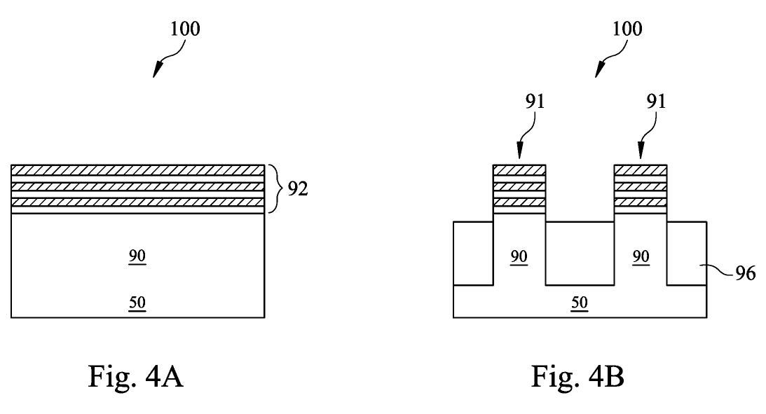

Next, in FIGS. 4A and 4B, shallow trench isolation (STI) regions 96 are formed over the substrate 50 and on opposing sides of the fin structures 91. As an example to form the STI regions 96, an insulation material may be formed over the substrate 50. The insulation material may be an oxide such as silicon oxide, a nitride, the like, or a combination thereof, and may be formed by a high-density plasma chemical vapor deposition (HDP-CVD), a flowable CVD (FCVD) (e.g., a CVD-based material deposition in a remote plasma system and post curing to make it convert to another material, such as an oxide), the like, or a combination thereof. Other insulation materials formed by any acceptable process may be used. In the illustrated embodiment, the insulation material is silicon oxide formed by an FCVD process. An anneal process may be performed after the insulation material is formed.

In some embodiments, the insulation material is formed such that excess insulation material covers the fin structures 91. In some embodiments, a liner is first formed along surfaces of the substrate 50 and fin structures 91, and a fill material, such as those discussed above is formed over the liner. In some embodiments, the liner is omitted.

Next, a removal process is applied to the insulation material to remove excess insulation material over the fin structures 91. The removal process also removes the mask 94, in the illustrated embodiment. In some embodiments, a planarization process such as a chemical mechanical planarization (CMP) process, an etch back process, combinations thereof, or the like, may be utilized. The planarization process exposes the layer stacks 92 such that top surfaces of the layer stacks 92 and the insulation material are level after the planarization process is completed. Next, the insulation material is recessed to form the STI regions 96. The insulation material is recessed such that the layer stacks 92 protrude from between neighboring STI regions 96. Top portions of the semiconductor fins 90 may also protrude from between neighboring STI regions 96. Further, the top surfaces of the STI regions 96 may have a flat surface as illustrated, a convex surface, a concave surface (such as dishing), or a combination thereof. The top surfaces of the STI regions 96 may be formed flat, convex, and/or concave by an appropriate etch. The STI regions 96 may be recessed using an acceptable etching process, such as one that is selective to the material of the insulation material (e.g., etches the material of the insulation material at a faster rate than other materials, such as the materials of the fin 90 and the layer stack 92). For example, a chemical oxide removal with a suitable etchant such as dilute hydrofluoric (dHF) acid may be used.

Next, in FIGS. 5A-5C, a dummy dielectric layer 97 is formed over the layer stack 92 and over the STI regions 96. The dummy dielectric layer 97 may be, for example, silicon oxide, silicon nitride, a combination thereof, or the like, and may be deposited or thermally grown according to acceptable techniques. In an embodiment, a layer of silicon is conformally formed over the layer stack 92 and over the upper surface of the STI regions 96, and a thermal oxidization process is performed to convert the deposited silicon layer into an oxide layer as the dummy dielectric layer 97.

Next, dummy gates 102 are formed over the fin structures 91. To form the dummy gates 102, a dummy gate layer may be formed over the dummy dielectric layer 97. The dummy gate layer may be deposited over the dummy dielectric layer 97 and then planarized, such as by a CMP. The dummy gate layer may be a conductive material and may be selected from a group including amorphous silicon, polycrystalline-silicon (polysilicon), poly-crystalline silicon-germanium (poly-SiGe), or the like. The dummy gate layer may be deposited by physical vapor deposition (PVD), CVD, sputter deposition, or other techniques known and used in the art. The dummy gate layer may be made of other materials that have a high etching selectivity from the STI regions 96.

Masks 104 are then formed over the dummy gate layer. The masks 104 may be formed from silicon nitride, silicon oxynitride, combinations thereof, or the like, and may be patterned using acceptable photolithography and etching techniques. In the illustrated embodiment, the mask 104 includes a first mask layer 104A (e.g., a silicon oxide layer) and a second mask layer 104B (e.g., a silicon nitride layer). The pattern of the masks 104 is then transferred to the dummy gate layer by an acceptable etching technique to form the dummy gates 102, and then transferred to the dummy dielectric layer by acceptable etching technique to form dummy gate dielectrics 97. The dummy gates 102 cover respective channel regions of the layer stacks 92. The pattern of the masks 104 may be used to physically separate each of the dummy gates 102 from adjacent dummy gates. The dummy gates 102 may also have a lengthwise direction substantially perpendicular to the lengthwise direction of the fin structures 91. The dummy gates 102 and the dummy gate dielectrics 97 are collectively referred to as dummy gate structures 101.

Next, a gate spacer layer 108 is formed by conformally depositing an insulating material over the layer stacks 92, the STI regions 96, and the dummy gates 102. The insulating material may be silicon nitride, silicon carbonitride, a combination thereof, or the like. In some embodiments, the gate spacer layer 108 includes multiple sublayers. For example, a first sublayer (sometimes referred to as a gate seal spacer layer) may be formed by thermal oxidation or a deposition, and a second sublayer (sometimes referred to as a main gate spacer layer) may be conformally deposited on the first sublayer.

FIGS. 5B and 5C illustrate cross-sectional views of the NSFET device 100 in FIG. 5A along cross-sections E-E and F-F in FIG. 5A, respectively. The cross-sections E-E and F-F correspond to cross-sections B-B and C-C in FIG. 1, respectively.

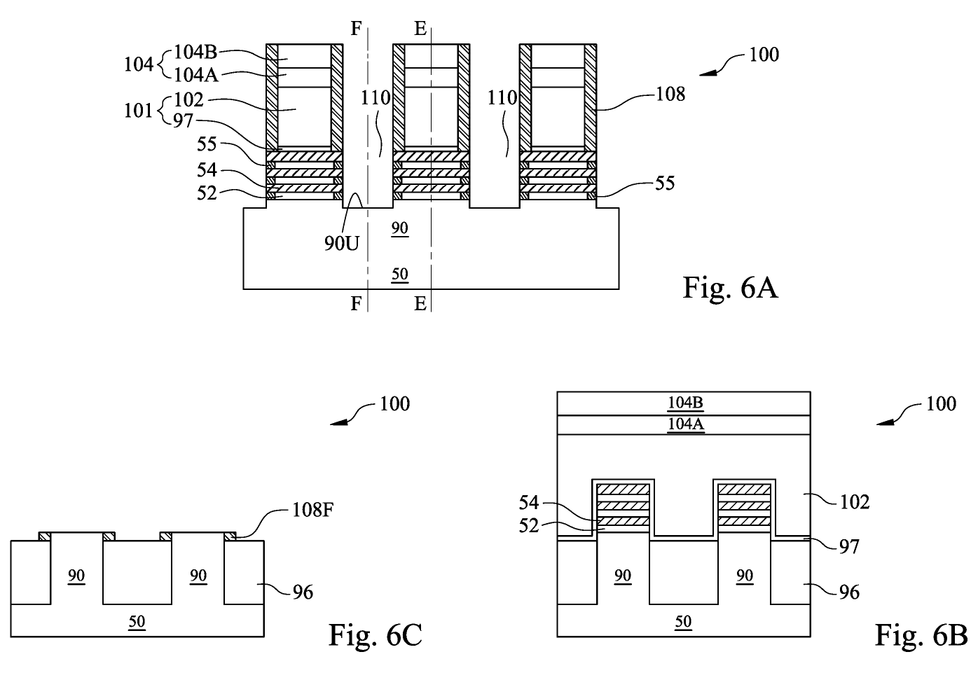

Next, in FIGS. 6A-6C, the gate spacer layer 108 is etched by an anisotropic etching process to form gate spacers 108. The anisotropic etching process may remove horizontal portions of the gate spacer layer 108 (e.g., portions over the STI regions 96 and the dummy gates 102), with remaining vertical portions of the gate spacer layer 108 (e.g., portions along sidewalls of the dummy gate structures 101) forming the gate spacers 108.

After the formation of the gate spacers 108, implantation for lightly doped source/drain (LDD) regions (not shown) may be performed. Appropriate type (e.g., p-type or n-type) impurities may be implanted into the exposed layer stacks 92 and/or fins 90. The n-type impurities may be any suitable n-type impurities, such as phosphorus, arsenic, antimony, or the like, and the p-type impurities may be any suitable p-type impurities, such as boron, BF₂, indium, or the like. The lightly doped source/drain regions may have a concentration of impurities between about 1E15/cm³ and about 1E16/cm³. An anneal process may be used to activate the implanted impurities.

Next, openings 110 (which may also be referred to as recesses, or source/drain openings) are formed in the layer stacks 92. The openings 110 may extend through the layer stacks 92 and into the fins 90. The openings 110 may be formed by an anisotropic etching process using, e.g., the dummy gate structures 101 and the gate spacers 108 as an etching mask.

After the openings 110 are formed, a selective etching process is performed to recess end portions of the first semiconductor material 52 exposed by the openings 110 without substantially attacking the second semiconductor material 54. After the selective etching process, recesses (also referred to as sidewall recesses) are formed in the first semiconductor material 52 at locations where the removed end portions used to be.

Next, an inner spacer layer is formed (e.g., conformally) in the openings 110 to line sidewalls and bottoms of the openings 110. The inner spacer layer also fills the sidewall recesses of the first semiconductor material 52 formed by the previous selective etching process. The inner spacer layer may be a suitable dielectric material, such as silicon carbonitride (SiCN), silicon oxycarbonitride (SiOCN), or the like, and may be formed by a suitable deposition method such as PVD, CVD, atomic layer deposition (ALD), or the like. Next, an etching process, such as an anisotropic etching process, is performed to remove portions of the inner spacer layer disposed outside the sidewall recesses of the first semiconductor material 52. The remaining portions of the inner spacer layer (e.g., portions disposed inside the sidewall recesses of the first semiconductor material 52) form inner spacers 55. As illustrated in FIG. 6A, the openings 110 expose sidewalls of the second semiconductor material 54, and expose upper surfaces 90U of the fins 90 at the bottoms of the openings 110.

FIGS. 6B and 6C illustrate cross-sectional views of the NSFET device 100 in FIG. 6A along cross-sections E-E and F-F, respectively. In the example of FIG. 6C, portions of the gate spacer layer 108 disposed on the upper surface of the STI regions 96 between neighboring fins 90 are completely removed by the anisotropic etching process used for forming the gate spacers 108. Remaining portions of the gate spacer layer 108 along the sidewalls of the fins 90 form fin spacers 108F. In FIG. 6C, the upper surface of the STI regions 96 between neighboring fins 90 is illustrated as a flat surface as a non-limiting example. The upper surface of the STI regions 96 between neighboring fins 90 may be curved (e.g., concave), e.g., due to the anisotropic etching process removing upper portions of the STI regions 96.

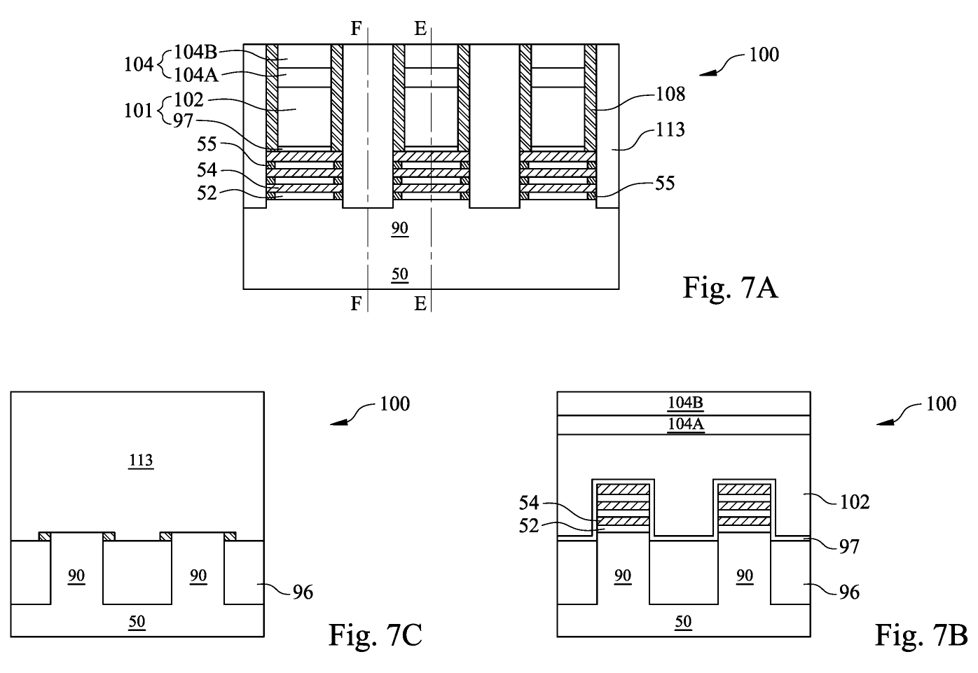

Next, in FIGS. 7A-7C, a dielectric material 113 is formed to fill the openings 110. In some embodiments, the dielectric material 113 is silicon oxide formed by a suitable formation method, such as CVD, FCVD, plasma-enhanced CVD (PECVD), atomic layer deposition (ALD), or the like. Other suitable materials, such as a low-K dielectric material, may also be used as the dielectric material 113. The dielectric material 113 may overfill the openings 110 and cover the upper surfaces of the masks 104. A planarization process, such as CMP, may be performed next to remove the dielectric material 113 from the upper surfaces of the masks 104. FIGS. 7B and 7C illustrate cross-sectional views of the NSFET device 100 in FIG. 7A along cross-sections E-E and F-F, respectively.

Next, in FIGS. 8A-8D, the dielectric material 113 is patterned, such that the dielectric material 113 is completely remove from the upper surfaces of the masks 104 and from some of the openings 110 (e.g., openings 110 in a first region 210 of the NSFET device 100), while other openings 110 (e.g., openings 110 in a second region 220 of the NSFET device 100) are partially filled with remaining portions of the dielectric material 113. The remaining portions of the dielectric material 113 form dielectric structures 113 in those openings 110.

In some embodiments, a plurality of etching processes using different etching masks are performed to pattern the dielectric material 113. Skilled artisans will readily appreciate that many different etching processes and/or etching masks may be used to achieve the etching results illustrated in FIGS. 8A-8D, details are not discussed here.

FIGS. 8B, 8C, and 8D illustrate cross-sectional views of the NSFET device 100 in FIG. 8A along cross-sections E-E, F-F, and G-G, respectively. The cross-section G-G corresponds to cross-section D-D in FIG. 1. Note that no dielectric material 113 is left in some of the openings 110 (e.g., opening 110 at the location of the cross-section F-F), while some other openings 110 (e.g., opening 110 at the location of the cross-section G-G) is partially filled with the remaining portions of the dielectric material 113 (e.g., the dielectric structures 113). In FIG. 8D, the dielectric structures 113 are disposed on upper surfaces of corresponding fins 90. In contrast, the upper surfaces of the fins 90 in FIG. 8C are exposed by the dielectric material 113 (e.g., free of the dielectric material 113).

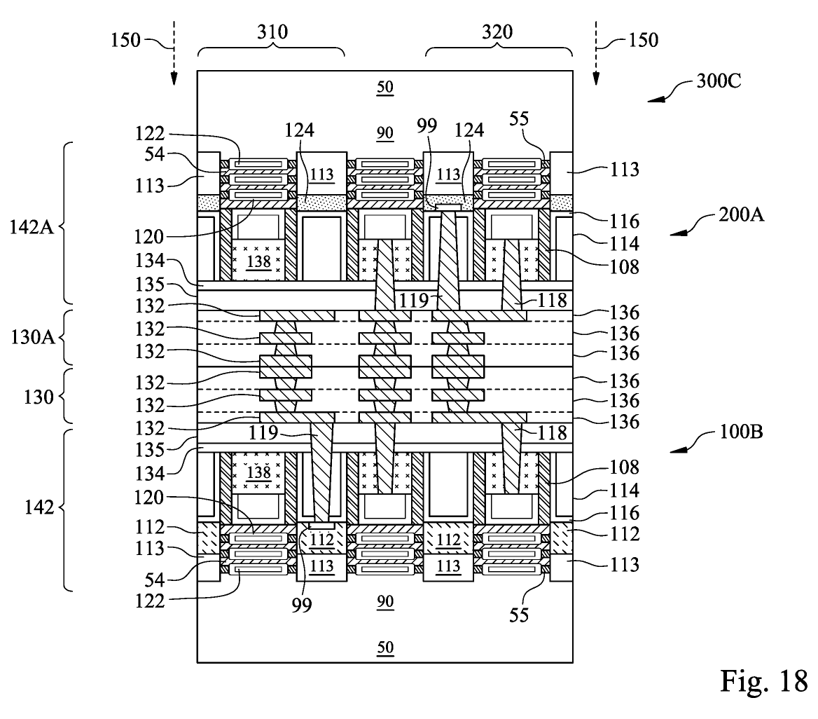

In the example of FIG. 8A, the upper surface 113U of the dielectric structure 113 is disposed between an upper surface and a lower surface of an inner spacer 55A, such that the dielectric structure 113 does not impede current flow through channel region(s) formed subsequently over the inner spacer 55A. The height of the dielectric structures 113 (or the location of the upper surface 113U of the dielectric structure 113) illustrated in FIG. 8A is merely a non-limiting example. The upper surface 113U of the dielectric structure 113 may be at any other suitable vertical locations (e.g., between the upper and lower surfaces of other inner spacers 55), as illustrated in the example of FIG. 18.

Next, in FIG. 9A-9D, source/drain regions 112 are formed in the openings 110. In the discussion herein, source/drain region(s) may refer to a source or a drain, individually or collectively dependent upon the context. In the illustrated embodiment, the source/drain regions 112 are formed of an epitaxial material(s), and therefore, may also be referred to as epitaxial source/drain regions 112. In some embodiments, the epitaxial source/drain regions 112 are formed in the openings 110 to exert stress in the respective channel regions of the NSFET device formed, thereby improving performance. In some embodiments, the epitaxial source/drain regions 112 are formed such that the dummy gate 102 is disposed between respective neighboring pairs of the epitaxial source/drain regions 112. In some embodiments, the gate spacers 108 are used to separate the epitaxial source/drain regions 112 from the dummy gates 102 by an appropriate lateral distance so that the epitaxial source/drain regions 112 do not short out subsequently formed replacement gate structures of the resulting NSFET device.

The epitaxial source/drain regions 112 are epitaxially grown in the openings 110, in some embodiments. The epitaxial source/drain regions 112 may include any acceptable material, such as appropriate for n-type or p-type device. For example, when n-type devices are formed, the epitaxial source/drain regions 112 may include materials exerting a tensile strain in the channel regions, such as silicon, SiC, SiCP, SiP, or the like. Likewise, when p-type devices are formed, the epitaxial source/drain regions 112 may include materials exerting a compressive strain in the channel regions, such as SiGe, SiGeB, Ge, GeSn, or the like. The epitaxial source/drain regions 112 may have surfaces raised from respective surfaces of the fins 90 and may have facets.

The epitaxial source/drain regions 112 and/or the fins 90 may be implanted with a dopant (e.g., n-type impurities or p-type impurities), similar to the process previously discussed for forming lightly-doped source/drain regions, followed by an anneal. The source/drain regions may have an impurity concentration (may also be referred to as a dopant concentration) of between about 1E19/cm³ and about 1E21/cm³. The n-type and/or p-type impurities for source/drain regions may be any of the impurities previously discussed. In some embodiments, the epitaxial source/drain regions 112 may be in situ doped during growth.

As a result of the epitaxy processes used to form the epitaxial source/drain regions 112, upper surfaces of the epitaxial source/drain regions 112 have facets which expand laterally outward beyond sidewalls of the fins 90. In the illustrated embodiment, adjacent epitaxial source/drain regions 112 remain separated (see FIGS. 9C and 9D) after the epitaxy process is completed. In other embodiments, these facets cause adjacent epitaxial source/drain regions 112 to merge together.

FIGS. 9B, 9C, and 9D illustrate cross-sectional views of the NSFET device 100 in FIG. 9A along cross-sections E-E, F-F, and G-G, respectively. As illustrated in FIGS. 9A, the source/drain regions 112 in the first region 210 of the NSFET device 100 extend from the upper surfaces 90U of the fins 90 to the uppermost layer of the second semiconductor material 54, and the source/drain regions 112 in the second region 220 of the NSFET device 100 extends from the upper surfaces 113U of the dielectric structures 113 to the uppermost layer of the second semiconductor material 54.

Still referring to FIGS. 9A-9D, next, a contact etch stop layer (CESL) 116 is formed (e.g., conformally) over the source/drain regions 112 and over the dummy gate structures 101, and a first inter-layer dielectric (ILD) 114 is then deposited over the CESL 116. The CESL 116 is formed of a material having a different etch rate than the first ILD 114, and may be formed of silicon nitride using PECVD, although other dielectric materials such as silicon oxide, silicon oxynitride, combinations thereof, or the like, and alternative techniques of forming the CESL 116, such as low-pressure CVD (LPCVD), PVD, or the like, could alternatively be used.

The first ILD 114 may be formed of a dielectric material, and may be deposited by any suitable method, such as CVD, PECVD, or FCVD. Dielectric materials for the first ILD 114 may include silicon oxide, Phospho-Silicate Glass (PSG), Boro-Silicate Glass (BSG), Boron-Doped Phospho-Silicate Glass (BPSG), undoped Silicate Glass (USG), or the like. Other insulation materials formed by any acceptable process may be used.

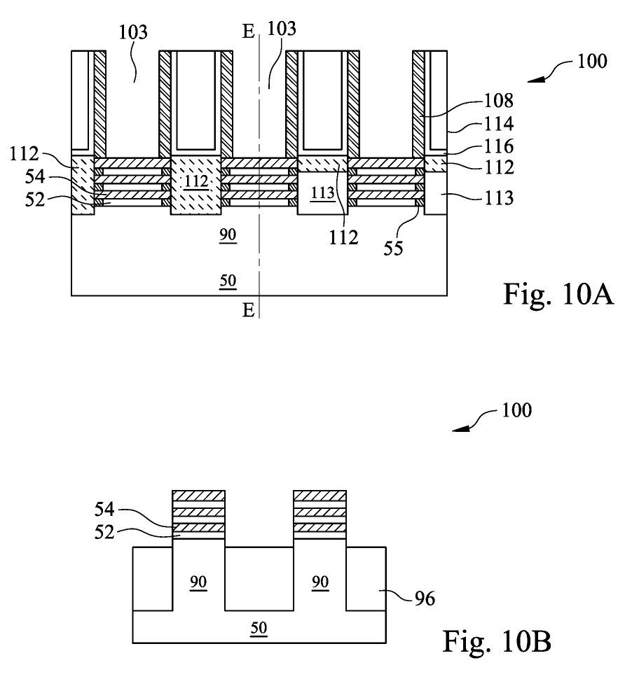

Next, in FIGS. 10A and 10B, the dummy gates 102 and the dummy gate dielectrics 97 are removed. FIG. 10B illustrates the cross-sectional view of the NSFET device 100 of FIG. 10A along the cross-section E-E. Note that for simplicity, the cross-sectional views along cross-sections F-F and G-G are not illustrated for processing steps hereinafter, because such cross-sectional views are the same as or similar to FIGS. 9C and 9D, or may be easily modified from FIGS. 9C and 9D (e.g., by adding additional layers formed over the first ILD 114).

To remove the dummy gates 102, a planarization process, such as a CMP, is performed to level the top surfaces of the first ILD 114 and the CESL 116 with the top surfaces of the dummy gates 102 and the gate spacers 108. The planarization process may also remove the masks 104 (see FIG. 9A) on the dummy gates 102, and portions of the gate spacers 108 along sidewalls of the masks 104. After the planarization process, top surfaces of the dummy gates 102, the gate spacers 108, the CESL 116, and the first ILD 114 are level. Accordingly, the top surfaces of the dummy gates 102 are exposed through the first ILD 114.

Next, the dummy gates 102 are removed in an etching step(s), so that recesses 103 (also referred to as gate trenches) are formed. In some embodiments, the dummy gates 102 are removed by an anisotropic dry etch process. For example, the etching process may include a dry etch process using reaction gas(es) that selectively etch the dummy gates 102 without etching the first ILD 114 or the gate spacers 108. During the removal of the dummy gates 102, the dummy gate dielectrics 97 may be used as an etch stop layer when the dummy gates 102 are etched. The dummy gate dielectrics 97 may then be removed after the removal of the dummy gates 102. An etching process, such as an isotropic etching process, may be performed to remove the dummy gate dielectrics 97. In an embodiment, an isotropic etching process using an etching gas that comprises HF and NH₃ is performed to remove the dummy gate dielectrics 97. As illustrated in FIGS. 10A and 10B, the recesses 103 expose the channel regions of the NSFET device 100. The channel regions are disposed between neighboring pairs of the epitaxial source/drain regions 112.

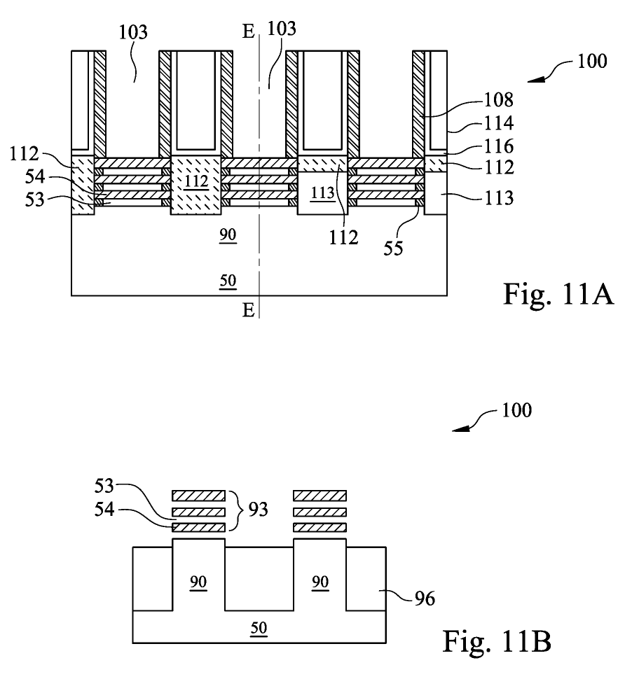

Next, in FIGS. 11A and 11B, the first semiconductor material 52 (e.g., portions exposed by the recesses 103) is removed to release the second semiconductor material 54. FIG. 11B illustrates the cross-sectional view of the NSFET device 100 along cross-section E-E in FIG. 11A. After the first semiconductor material 52 is removed, the second semiconductor material 54 (e.g., portions underlying the dummy gates 102 before the dummy gates 102 are removed) forms a plurality of nanostructures 54 that extend horizontally (e.g., parallel to the major upper surface of the substrate 50). The nanostructures 54 may be collectively referred to as the channel regions 93 or the channel layers 93 of the NSFET device 100 formed. As illustrated in FIGS. 11A and 11B, gaps 53 (e.g., empty spaces) are formed between the nanostructures 54 by the removal of the first semiconductor material 52. In some embodiments, the nanostructures 54 are nanosheets or nanowires, depending on, e.g., the dimensions (e.g., size and/or aspect ratio) of the nanostructures 54.

In some embodiments, the first semiconductor material 52 is removed by a selective etching process using an etchant that is selective to (e.g., having a higher etch rate for) the first semiconductor material 52, such that the first semiconductor material 52 is removed without substantially attacking the second semiconductor material 54. In some embodiments, an isotropic etching process is performed to remove the first semiconductor material 52. The isotropic etching process is performed using an etching gas, and optionally, a carrier gas. The etching gas comprises F₂ and HF, and the carrier gas may be an inert gas such as Ar, He, N₂, combinations thereof, or the like, in some embodiments.

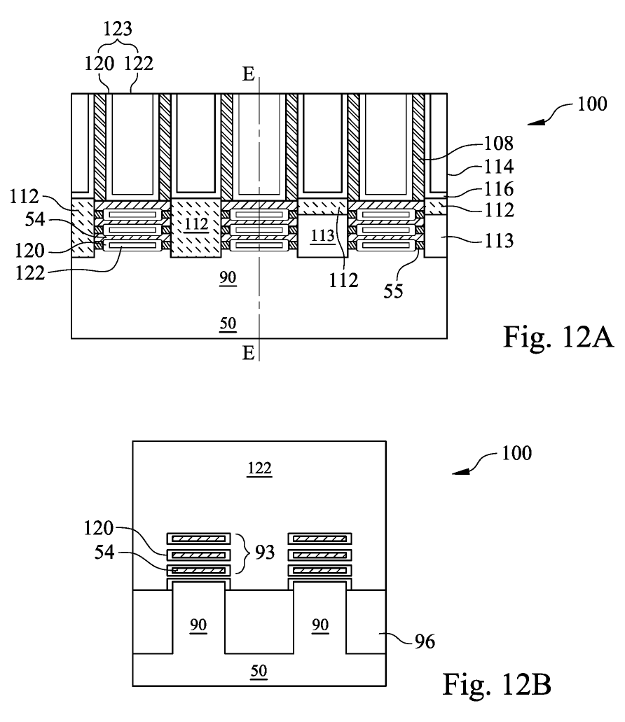

Next, in FIGS. 12A and 12B, a gate dielectric material 120 and a gate electrode material 122 are formed in the recesses 103 to form replacement gate structures 123. FIG. 12B illustrates the cross-sectional view of the NSFET device 100 along cross-section E-E in FIG. 12A. The gate dielectric material 120 is deposited conformally in the recesses 103, such as on the top surfaces and the sidewalls of the semiconductor fins 90, and on sidewalls of the gate spacers 108. The gate dielectric material 120 may also be formed on the top surface of the first ILD 114. Notably, the gate dielectric material 120 is formed to wrap around the nanostructures 54. In accordance with some embodiments, the gate dielectric material 120 comprises silicon oxide, silicon nitride, or multilayers thereof. In some embodiments, the gate dielectric material 120 is formed of a high-K dielectric material, and in these embodiments, the gate dielectric material 120 may have a dielectric value (also referred to as K value) greater than about 7.0, and may include a metal oxide or a silicate of Hf, Al, Zr, La, Mg, Ba, Ti, or Pb, or combinations thereof. The formation methods of the gate dielectric material 120 may include Molecular-Beam Deposition (MBD), ALD, PECVD, and the like.

Next, the gate electrode material 122 is deposited over and around the gate dielectric material 120, and fills the remaining portions of the recesses 103. The gate electrode material 122 may include a metal-containing material such as TiN, TiO, TaN, TaC, Co, Ru, Al, W, combinations thereof, or multi-layers thereof. For example, although a single-layer gate electrode material 122 is illustrated, the gate electrode material 122 may comprise any number of liner layers (e.g., barrier layers), any number of work function tuning layers, and a fill material (e.g., a fill metal, an electrically conductive material). After the gate electrode material 122 is formed, a planarization process, such as a CMP, may be performed to remove excess portions of the gate dielectric material 120 and the gate electrode material 122, which excess portions are over the top surface of the first ILD 114. The remaining portions of the gate electrode material 122 and the gate dielectric material 120 thus form the gate electrodes 122 and the gate dielectric layers 120 of the replacement gate structures 123 of the resulting NSFET device 100, respectively. Each gate electrode 122 and the corresponding gate dielectric layer 120 may be collectively referred to as a gate stack, a replacement gate structure, a metal gate structure, or a gate structure. Each gate structure 123 extends around the respective nanostructures 54.

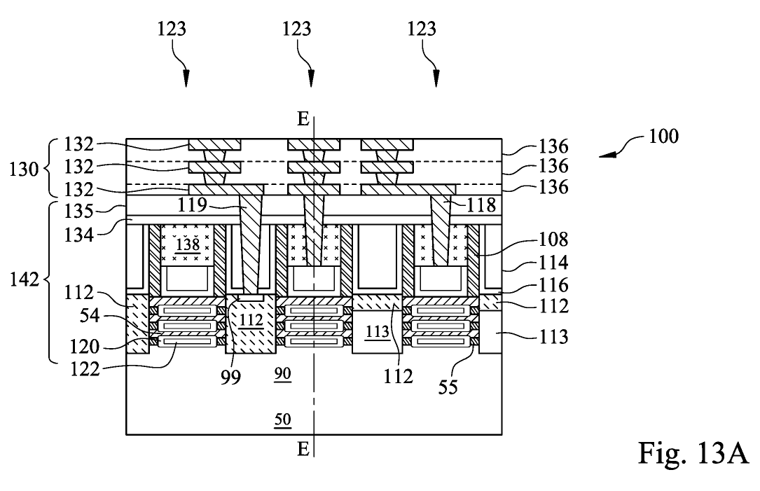

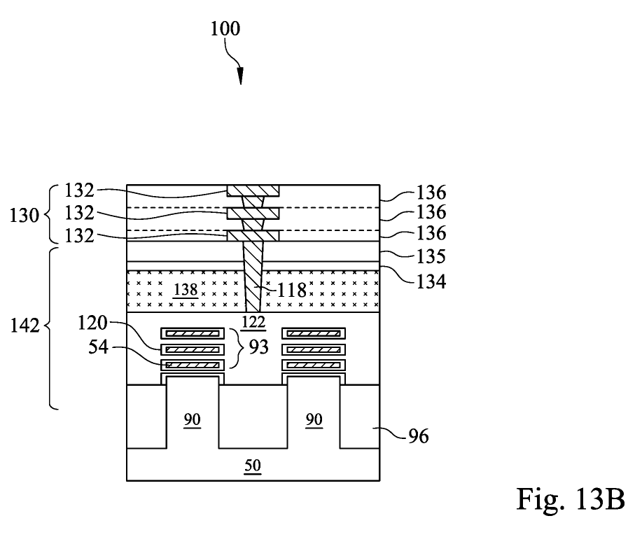

Next, in FIGS. 13A and 13B, gate masks 138 are formed over the replacement gate structures 123. FIG. 13B illustrates the cross-sectional view of the NSFET device 100 along cross-section E-E in FIG. 13A. The formation process of the gate masks 138 may include recessing replacement gate structures 123, filling the resulting recesses with a dielectric material such as silicon nitride, silicon carbonitride, silicon oxynitride, silicon oxycarbonitride, or the like, and performing a planarization process to remove excess portions of the dielectric material over the first ILD 114. The remaining portions of the dielectric material form the gate masks 138. FIG. 13B illustrates the cross-sectional view of the NSFET device 100 along cross-section E-E in FIG. 13A.

Next, an etch stop layer (ESL) 134 and a second ILD 135 are formed sequentially over the first ILD 114 and the gate masks 138. In some embodiments, The ESL 134 may include a dielectric material having a high etching selectivity from the etching of the second ILD 135, such as aluminum oxide, aluminum nitride, silicon oxycarbide, or the like. The second ILD 135 may be formed using flowable CVD, ALD, or the like, and the material may include PSG, BSG, BPSG, USG, or the like, which may be deposited by any suitable method, such as CVD, PECVD, or the like.

Next, source/drain contact openings are formed to extend through the second ILD 135, the ESL 134, the first ILD 114, and the CESL 116 to expose the source/drain regions 112. Similarly, gate contact openings are formed to extend through the second ILD 135, the ESL 134, and the gate masks 138 to expose the (recessed) replacement gate structures 123. Next, silicide regions 99 are formed on the source/drain regions 112, and source/drain contact plugs 119 are formed on the silicide regions 99 to electrically couple to the source/drain regions 112. In addition, gate contact plugs 118 are formed in the gate contact openings to electrically couple to the replacement gate structures 123.

In some embodiments, the silicide regions 99 are formed by depositing a metal capable of reacting with semiconductor materials (e.g., silicon, germanium) to form silicide or germanide regions, such as nickel, cobalt, titanium, tantalum, platinum, tungsten, other noble metals, other refractory metals, rare earth metals or their alloys, over the source/drain regions 112, then performing a thermal anneal process to form the silicide regions 99. The un-reacted portions of the deposited metal are then removed, e.g., by an etching process. Although regions 99 are referred to as silicide regions, regions 99 may also be germanide regions, or silicon germanide regions (e.g., regions comprising silicide and germanide).

The source/drain contact plugs 119 and the gate contact plugs 118 may be formed by filling the source/drain contact openings and the gate contact openings with an electrically conductive material(s), such as tungsten, although other suitable materials such as aluminum, copper, tungsten nitride, ruthenium, silver, gold, rhodium, molybdenum, nickel, cobalt, cadmium, zinc, alloys of these, combinations thereof, and the like, may alternatively be utilized. A planarization process, such as CMP, may be performed to remove excess portions of the electrically conducive material(s) that are disposed outside of the source/drain contact openings and the gate contact openings. The number and the location of the source/drain contact plugs 119 and the gate contact plugs 118 illustrated in the figures are illustrative and non-limiting, as skilled artisans readily appreciate.

In FIGS. 13A and 13B, the layers of the NSFET device 100 disposed between upper portions of the fins 90 and the second ILD 135 are collectively referred to as the device layer 142 of the NSFET device 100.

Next, a front-side interconnect structure 130 is formed on the device layer 142. The front-side interconnect structure 130 includes dielectric layers 136 and layers of conductive features 132 in the dielectric layers 136. The dielectric layers 136 may include low-K dielectric layers formed of low-K dielectric materials. The dielectric layers 136 may further include passivation layers, which are formed of non-low-K and dense dielectric materials such as Undoped Silicate-Glass (USG), silicon oxide, silicon nitride, or the like, or combinations thereof over the low-K dielectric materials. The dielectric layers 136 may also include polymer layers.

The conductive features 132 may include conductive lines and vias, which may be formed using, e.g., damascene processes. The metal lines and vias may include diffusion barriers and a copper containing material over the diffusion barriers. The front-side interconnect structure 130 may also include aluminum pads over and electrically connected to the metal lines and vias. Depending on how the respective die is to be packaged, the topmost conductive features among the conductive features 132 may include bond pads, metal pillars, solder regions, and/or the like.

FIG. 14 illustrates a cross-sectional view of an NSFET device 200. The NSFET device 200 is similar to the NSFET device 100 and may be formed using a same or similar formation method, but the source/drain regions 124 of the NSFET device 200 has a different conductivity type (e.g., N-type or P-type) from the source/drain regions 112 of the NSFET device 100, in some embodiments. For example, the source/drain regions 112 of the NSFET device 100 may have a first doping type (e.g., doped with a dopant of a first conductivity type, such as N-type), and the source/drain regions 124 of the NSFET device 200 may have a second doping type (e.g., doped with a dopant of a second conductivity type, such as P-type) different from the first doping type. In other words, one of the NSFET devices 100 and 200 may be formed using N-type NSFETs, and the other one of the NSFET devices 100 and 200 may be formed using P-type NSFETs. The source/drain regions 124 may be formed using a same or similar formation method as the source/drain regions 112, thus details are not repeated. The cross-sectional view of the NSFET device 200 along cross-section E-E in FIG. 14 is same as or similar to that in FIG. 13B, thus not repeated here.

In FIG. 14, the layers of the NSFET device 200 disposed between upper portions of the fins 90 and the second ILD 135 are collectively referred to as the device layer 142A of the NSFET device 200. FIG. 14 further illustrates the front-side interconnect structure 130A formed over the device layer 142A. The front-side interconnect structure 130A is same as or similar to the front-side interconnect structure 130, thus details are not repeated here. The front-side interconnect structure 130A of the NSFET device 200 is then bonded to the front-side interconnect structure 130 of the NSFET device 100 to form a CFET device 300, details are discussed hereinafter.

Next, in FIGS. 15A and 15B, the NSFET device 200 is flipped upside-down, and the front-side interconnect structure 130A is bonded to the front-side interconnect structure 130 of the NSFET device 100. FIG. 15B illustrates the cross-sectional view of the CFET device 300 along cross-section E-E in FIG. 15A. In some embodiments, direct bonding is used to bond the front-side interconnect structure 130A and the front-side interconnect structure 130 without using an intermediate layer (e.g., solder). In some embodiments, in a direct bonding process, direct metal-to-metal bonding and direct dielectric-to-dielectric bonding are utilized to achieve a robust and reliable connection at the interface of two devices. Metal-to-metal bonding involves aligning and applying sufficient pressure on metal surfaces, such as copper or aluminum surfaces, often accompanied by thermal treatment to facilitate atomic diffusion and interfacial adhesion without an intermediate layer. Simultaneously, dielectric-to-dielectric bonding uses surfaces such as silicon dioxide or other insulating materials, which, when aligned under appropriate conditions (e.g., at elevated temperatures and/or with pressure applied at the surfaces), form bonds through forces such as Van der Waals force or covalent interactions. The direct bonding technique is instrumental in creating high-density, low-resistance connections while reducing or minimizing thermal budgets. Besides direct bonding, other bonding techniques, such as bonding using solder regions, are also possible and are fully intended to be included within the scope of the preset disclosure.

In some embodiments, multiple NSFET devices 100 are formed on a first wafer (e.g., a substrate 50), and multiple NSFET devices 200 are formed on a second wafer (e.g., another substrate 50). After the front-side interconnect structures 130 and 130A are bonded together, a wafer-on-wafer structure is formed that comprises multiple CFET devices 300. Next, a dicing process is performed along dicing regions indicated by the dashed lines 150 in FIG. 15A to separate the wafer-on-wafer structure into individual (e.g., separate) CFET devices 300, where each of the CFET devices 300 includes an NSFET device 100 and an NSFET device 200 stacked vertically (e.g., bonded together). In the illustrated embodiments, the NSFET devices 100 and 200 in the CFET device 300 are of different conductivity types. This is, of course, merely a non-limiting example. The NSFET devices 100 and 200 in the CFET device 300 may be of the same conductivity type.

In the example of FIG. 15A, in a first region 310 of the CFET device 300, the source/drain regions 112 (or 124) on opposing sides of a gate structure 123 contact all of the nanostructures 54 of that gate structure 123. In other words, the source/drain regions 112 (or 124) extend continuously from the upper surface 90U of the respective fin 90 to an uppermost nanostructure 54 distal from the respective substrate 50. Stated in another way, all of the nanostructures 54 of that gate structure 123 are disposed between a pair of source/drain regions 112 (or 124) on opposing sides of that gate structure 123. Therefore, during operation of the CFET device 300, electrical current flows through all of the nanostructures 54 of that gate structure 123. In contrast, in a second region 320 of the CFET device 300, the source/drain regions 112 (or 124) on opposing sides of a gate structure 123 contact a first subset (e.g., the topmost nanostructure) of the nanostructures 54 of that gate structure 123, and the dielectric structures 113 contact a second subset (e.g., the two nanostructures under the topmost nanostructure) of the nanostructures 54 of that gate structure 123. Therefore, during operation of the CFET device 300, electrical current flows through the first subset of the nanostructures 54 of that gate structure 123, and no electrical current flows through the second subset of the nanostructures 54 of that gate structure 123. For ease of discussion, the second subset of nanostructures 54 are referred to as inactive nanostructures 54 (or dummy nanostructures 54), and first subset of the nanostructures 54 are referred to as active nanostructures 54. Note that in the example of FIG. 15A, all of the nanostructures 54 in the first region 310 are active nanostructures 54. Since the NSFET device 100 (or 200) includes both active nanostructures 54 and inactive nanostructures 54, the NSFET device 100 (or 200) is also referred to as a hybrid NSFET device.

The disclosed CFET device 300 (and other embodiments, such as 300A, 300B, 300C, and 300D) achieves many advantages. Compared with a monolithic CFET formation process, where the vertically stacked NSFETs are formed over a same substrate (e.g., a same wafer), the disclosed embodiments herein use a sequential CFET formation process, where a first type (e.g., N-type) of NSFETs are formed on a first wafer, and a second type (e.g., P-type) of NSFETs are formed on a second wafer. The first wafer and the second wafer are then bonded together through a front-side to front-side bonding, where a first interconnect structure (e.g., 130) formed on a front-side of the first wafer is bonded to a second interconnect structure (e.g., 130A) formed on a front-side of the second wafer. The disclosed sequential CFET formation process alleviates or avoids challenges encountered by the monolithic CFET formation process, such as high aspect ratio (AR) etching (e.g., for forming openings with high AR) or metal gap filling in high AR openings.

In addition, the front-side to front-side bonding through interconnect structures offers additional advantages compared with a reference sequential CFET formation process, where the front-side of a first wafer is bonded to a backside of a second wafer through a backside to front-side bonding. After the bonding, the reference sequential CFET formation process forms an interconnect structure over the front-side of the second wafer, which interconnect structure may include vias that extend vertically from the top wafer (e.g., the second wafer) to the bottom wafer (e.g., the first wafer) to electrically couple, e.g. respective source/drain regions on both wafers. The reference sequential CFET formation process may face many challenges. For example, to ensure that respective features (e.g., source/drain regions, gate structures) on both wafers are aligned vertically, the alignment between the two wafers has to be very accurate and may be difficult to achieve. In addition, vias that extend from the top wafer to the bottom wafer may need extra area to implement, and may increase the RC delay of the device formed. In contrast, the disclosed sequential CFET formation process, by forming the front-side interconnect structures 130 and 130A and bonding through front-side to front-side bonding, obviate the need to form vias that extend from the top wafer to the bottom wafer, thus reducing the area required for implementation (thus improving integration density), and reducing the RC delay of the device formed. The front-side interconnect structures 130 and 130A are formed by the back-end-of-line (BEOL) process of semiconductor manufacturing, and offer flexibility (e.g., design freedom) regarding the locations of the conductive features of the interconnect structures. Due to the larger size of, e.g., the conductive pad of the interconnect structures used for bonding, proper alignment between the top wafer and the bottom wafer is much easier to achieve.

Furthermore, the constituent NSFET device (e.g., 100 or 200) of the CFET device 300 may be a hybrid NSFET device that includes different numbers of active nanostructures 54 in different regions of the CFET device 300. For example, in FIG. 15A, the NSFETs formed in the first region 310 have a larger number of active nanostructures 54 than the NSFETs formed in the second region 320. The larger number of active nanostructures 54 allow larger channel current for the NSFETs, thus the NSFETs in the first region 310 may be well suited for forming high-performance computing (HPC) devices that require high driving current. In contrast, the NSFETs formed in the region 320 have a smaller number of active nanostructures 54, thus consuming less current during operation. Therefore, the NSFETs in the second region 320 may be well suited for forming low-power circuits or circuits not requiring high driving current, e.g., circuits in some system-on-chip (SoC) devices. Therefore, the disclosed embodiments allow devices with different driving current requirements to be integrated on a same substrate, thus achieving greater design flexibility and integration density.

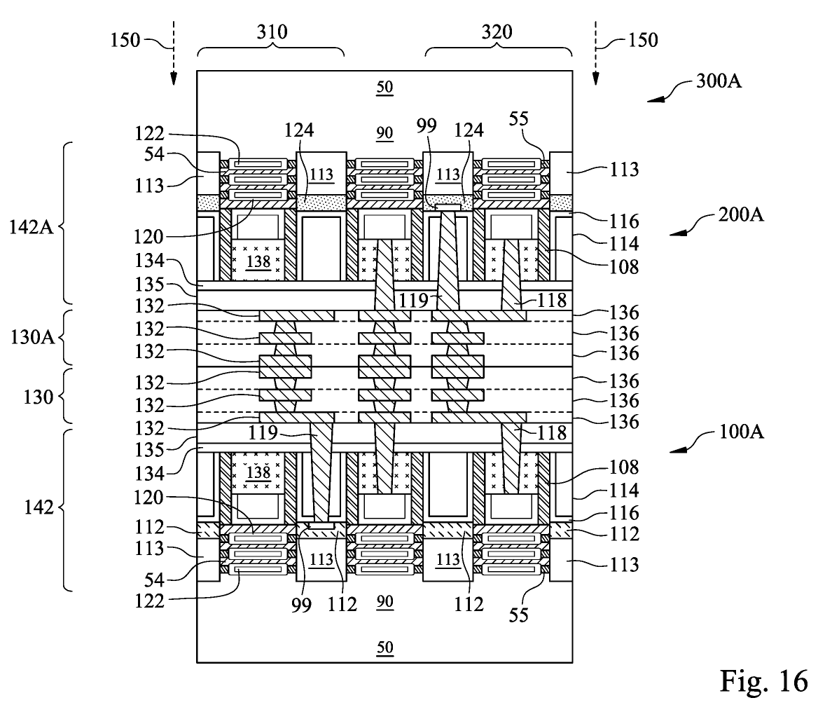

FIG. 16 illustrates a cross-sectional view of a CFET device 300A, in accordance with another embodiment. The CFET device 300A is similar to the CFET device 300, but the numbers of active nanostructures 54 in the constituent NSFET devices 100A and 200A are different from those of CFET device 300. In particular, each NSFET in the NSFET devices 100A (or 200A) has one active nanostructure 54. The cross-sectional view of the CFET device 300A (or 300B, 300C, 300D) along cross-section E-E (see, e.g., FIG. 15A) is the same as or similar to that in FIG. 15B, thus not repeated here.

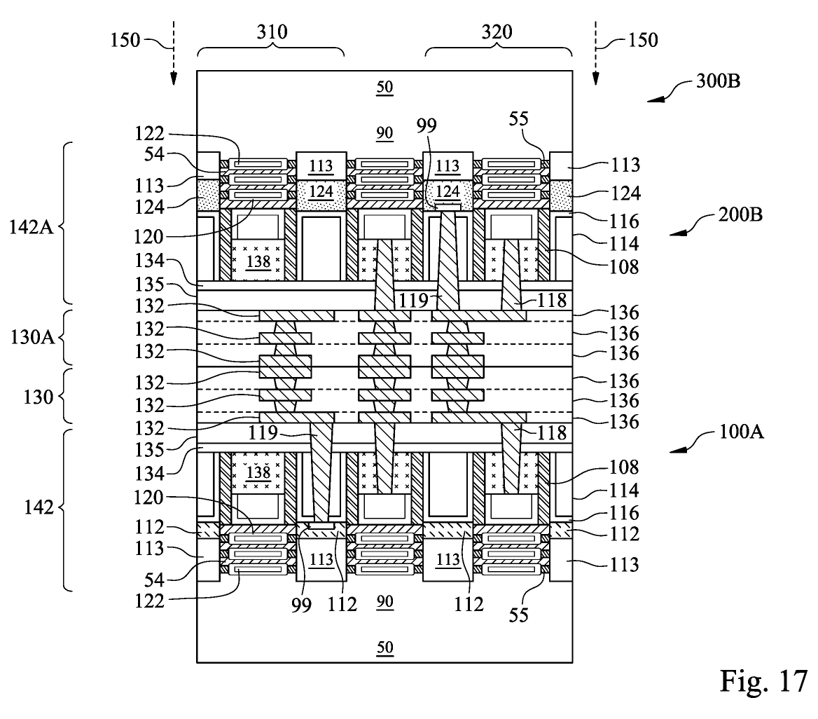

FIG. 17 illustrates a cross-sectional view of a CFET device 300B, in accordance with another embodiment. The CFET device 300B is similar to the CFET device 300, but the numbers of active nanostructures 54 in the constituent NSFET devices 100A and 200B are different from those of CFET device 300. In particular, each NSFET in the NSFET devices 100A has one active nanostructure 54, and each NSFET in the NSFET devices 200B has two active nanostructures 54.

FIG. 18 illustrates a cross-sectional view of a CFET device 300C, in accordance with another embodiment. The CFET device 300C is similar to the CFET device 300, but the numbers of active nanostructures 54 in the constituent NSFET devices 100B and 200A are different from those of CFET device 300. In particular, each NSFET in the NSFET devices 100B has two active nanostructures 54, and each NSFET in the NSFET devices 200A has one active nanostructure 54.

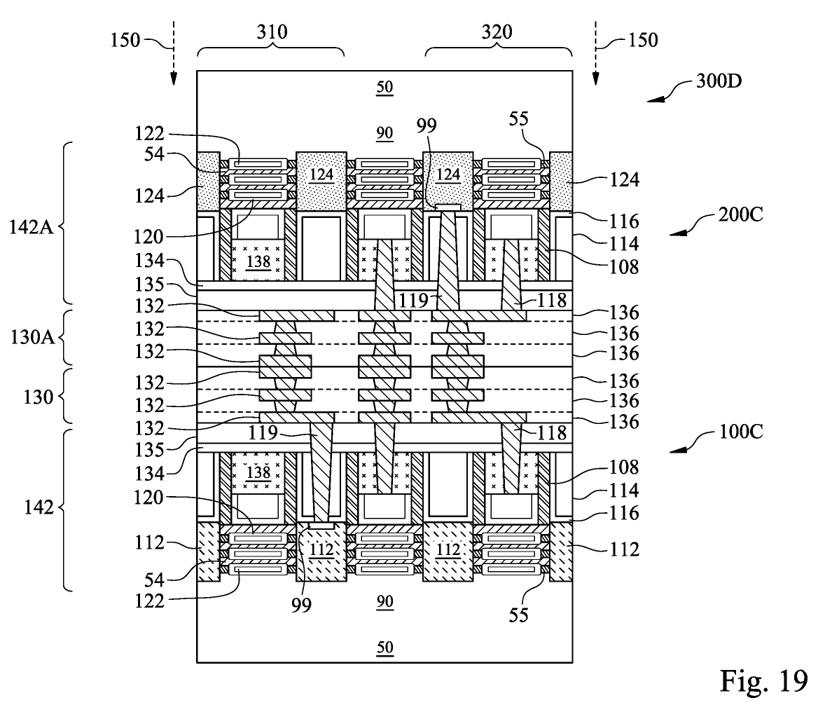

FIG. 19 illustrates a cross-sectional view of a CFET device 300D, in accordance with yet another embodiment. The CFET device 300D is similar to the CFET device 300, but the numbers of active nanostructures 54 in the constituent NSFET devices 100C and 200C are different from those of CFET device 300. In particular, each NSFET in the NSFET devices 100C (or 200C) has three active nanostructures 54 (which is the total number of nanostructures 54 available in the illustrated example).

Skilled artisans will readily appreciate that besides the disclosed embodiments, other embodiments are possible. For example, the numbers of active nanostructures 54 and inactive nanostructures 54 in each region (e.g., 310, 320) and/or each constituent NSFET device of the CFET device may be modified to arrive at other embodiments. These and other variations are fully intended to be included within the scope of the present disclosure.

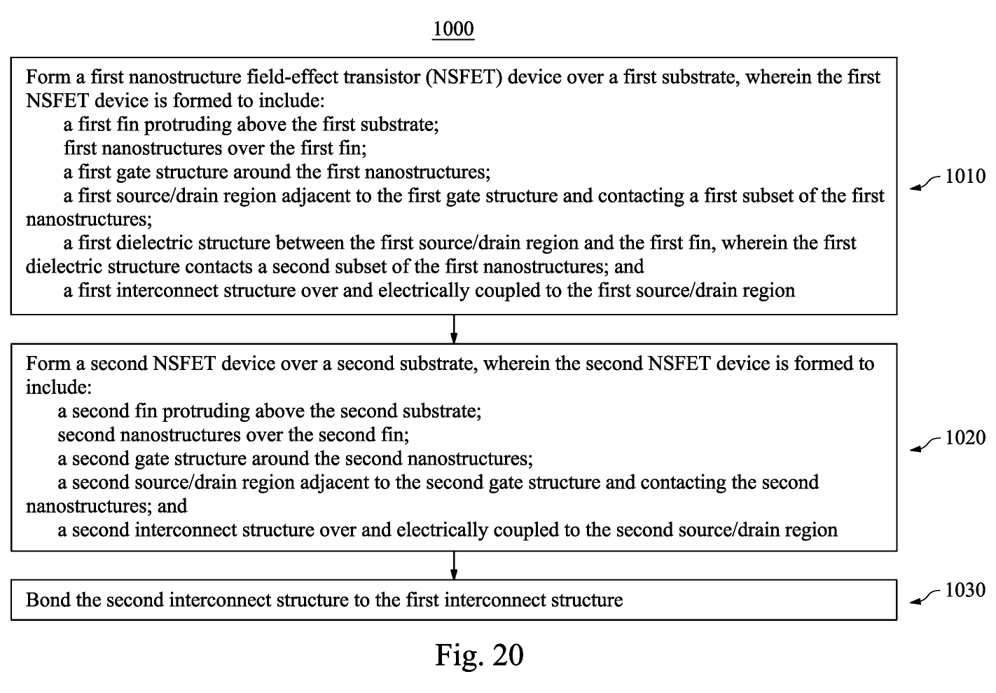

FIG. 20 illustrates a flow chart of a method 1000 of forming a semiconductor device, in accordance with some embodiments. It should be understood that the embodiment method shown in FIG. 20 is merely an example of many possible embodiment methods. One of ordinary skill in the art would recognize many variations, alternatives, and modifications. For example, various steps as illustrated in FIG. 20 may be added, removed, replaced, rearranged, or repeated.

Referring to FIG. 20, at block 1010, a first nanostructure field-effect transistor (NSFET) device is formed over a first substrate, wherein the first NSFET device is formed to include: a first fin protruding above the first substrate; first nanostructures over the first fin; a first gate structure around the first nanostructures; a first source/drain region adjacent to the first gate structure and contacting a first subset of the first nanostructures; a first dielectric structure between the first source/drain region and the first fin, wherein the first dielectric structure contacts a second subset of the first nanostructures; and a first interconnect structure over and electrically coupled to the first source/drain region. At block 1020, a second NSFET device is formed over a second substrate, wherein the second NSFET device is formed to include: a second fin protruding above the second substrate; second nanostructures over the second fin; a second gate structure around the second nanostructures; a second source/drain region adjacent to the second gate structure and contacting the second nanostructures; and a second interconnect structure over and electrically coupled to the second source/drain region. At block 1030, the second interconnect structure is bonded to the first interconnect structure.

In an embodiment, a semiconductor device includes: a first substrate; a first fin protruding above the first substrate; first nanostructures over the first fin; a first gate structure around the first nanostructures; a first source/drain region adjacent to the first gate structure and contacting a first subset of the first nanostructures; a first dielectric structure between the first source/drain region and the first fin, wherein the first dielectric structure contacts a second subset of the first nanostructures; second nanostructures over the first fin and laterally spaced apart from the first nanostructures; a second gate structure around the second nanostructures; and a second source/drain region adjacent to the second gate structure and contacting the second nanostructures. In an embodiment, a first height of the first source/drain region, measured along a first direction perpendicular to a major upper surface of the first substrate, is smaller than a second height of the second source/drain region measured along the first direction. In an embodiment, the semiconductor device further includes: first inner spacers between adjacent ones of the first nanostructures; and second inner spacers between adjacent ones of the second nanostructures, wherein an interface between the first source/drain region and the first dielectric structure is disposed between an upper surface of a first one of the first inner spacers and a lower surface of the first one of the first inner spacers. In an embodiment, the semiconductor device further includes: a first dielectric layer over the first source/drain region, over the second source/drain region, around the first gate structure, and around the second gate structure; and a first interconnect structure over the first dielectric layer, wherein the first interconnect structure is electrically coupled to at least one of the first gate structure, the second gate structure, the first source/drain region, and the second source/drain region. In an embodiment, the semiconductor device further includes: a second substrate; a second fin protruding above the second substrate; third nanostructures over the second fin; a third gate structure around the third nanostructures; a third source/drain region adjacent to the third gate structure and contacting the third nanostructures; a second dielectric layer over the third source/drain region around the third gate structure; and a second interconnect structure over the second dielectric layer, wherein the second interconnect structure is electrically coupled to at least one of the third gate structure and the third source/drain region, wherein the second interconnect structure is bonded to the first interconnect structure. In an embodiment, the first source/drain region and the second source/drain region have a first doping type, wherein the third source/drain region has a second doping type different from the first doping type. In an embodiment, the second interconnect structure is bonded to the first interconnect structure through direct metal-to-metal bonding and direct dielectric-to-dielectric bonding, wherein there is no solder region between the second interconnect structure and the first interconnect structure. In an embodiment, the semiconductor device further includes: fourth nanostructures over the second fin and laterally spaced apart from the third nanostructures; a fourth gate structure around the fourth nanostructures; a fourth source/drain region adjacent to the fourth gate structure and contacting a first subset of the fourth nanostructures; and a second dielectric structure between the fourth source/drain region and the second fin, wherein the second dielectric structure contacts a second subset of the fourth nanostructures. In an embodiment, the first gate structure and the fourth gate structure are aligned vertically along a first line, wherein the second gate structure and the third gate structure are aligned vertically along a second line. In an embodiment, the first subset of the first nanostructures and the first subset of the fourth nanostructures have a same number of nanostructures.

In an embodiment, a semiconductor device includes a first nanostructure field-effect transistor (NSFET) device that comprises: a first substrate; a first fin protruding above the first substrate; first nanostructures over the first fin; a first gate structure around the first nanostructures; a first source/drain region adjacent to the first gate structure and contacting a first subset of the first nanostructures; a first dielectric structure between the first source/drain region and the first fin, wherein the first dielectric structure contacts a second subset of the first nanostructures; and a first interconnect structure over and electrically coupled to the first source/drain region. The semiconductor device further includes a second NSFET device that comprises: a second substrate; a second fin protruding above the second substrate; second nanostructures over the second fin; a second gate structure around the second nanostructures; a second source/drain region adjacent to the second gate structure and contacting the second nanostructures; and a second interconnect structure over and electrically coupled to the second source/drain region, wherein the second interconnect structure is bonded to the first interconnect structure. In an embodiment, the first source/drain region is of a first conductivity type, and the second source/drain region is of a second conductivity type different from the first conductivity type. In an embodiment, the second source/drain region extends continuously from an upper surface of the second fin distal from the second substrate to an uppermost surface of the second nanostructures distal from the second substrate. In an embodiment, the first NSFET device further comprises: third nanostructures over the first fin and laterally adjacent to the first nanostructures; a third gate structure around the third nanostructures; and a third source/drain region adjacent to the third gate structure and contacting the third nanostructures, wherein the third source/drain region extends continuously from an upper surface of the first fin distal from the first substrate to an uppermost surface of the third nanostructures distal from the first substrate. In an embodiment, the second source/drain region contacts a first subset of the second nanostructures, wherein the second NSFET device further comprises a second dielectric structure between the second source/drain region and the second fin, wherein the second dielectric structure contacts a second subset of the second nanostructures. In an embodiment, the first source/drain region and the second source/drain region are vertically aligned along a same line.

In an embodiment, a method of forming a semiconductor device includes forming a first nanostructure field-effect transistor (NSFET) device over a first substrate, wherein the first NSFET device is formed to include: a first fin protruding above the first substrate; first nanostructures over the first fin; a first gate structure around the first nanostructures; a first source/drain region adjacent to the first gate structure and contacting a first subset of the first nanostructures; a first dielectric structure between the first source/drain region and the first fin, wherein the first dielectric structure contacts a second subset of the first nanostructures; and a first interconnect structure over and electrically coupled to the first source/drain region. The method also includes forming a second NSFET device over a second substrate, wherein the second NSFET device is formed to include: a second fin protruding above the second substrate; second nanostructures over the second fin; a second gate structure around the second nanostructures; a second source/drain region adjacent to the second gate structure and contacting the second nanostructures; and a second interconnect structure over and electrically coupled to the second source/drain region. The method further includes bonding the second interconnect structure to the first interconnect structure. In an embodiment, the bonding comprises performing a direct bonding between the second interconnect structure and the first interconnect structure without using a solder material. In an embodiment, the first NSFET device is formed to further include: third nanostructures over the first fin and laterally adjacent to the first nanostructures; a third gate structure around the third nanostructures; and a third source/drain region adjacent to the third gate structure and contacting the third nanostructures, wherein the third source/drain region extends continuously from an upper surface of the first fin distal from the first substrate to an uppermost surface of the third nanostructures distal from the first substrate. In an embodiment, the first substrate is a first wafer, and the second substrate is a second wafer, wherein after the bonding, other semiconductor devices are formed besides the semiconductor device, wherein the method further comprises, after the bonding, performing a dicing process to separate the semiconductor device from the other semiconductor devices.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a complementary field-effect transistor (CFET) device, comprising:
forming a first nanostructure field-effect transistor (NSFET) device, comprising:
forming a first fin structure protruding above a first substrate, the first fin structure comprising a first fin and a first layer stack over the first fin, wherein the first layer stack comprises layers of a first semiconductor material interleaved with layers of a second semiconductor material;
forming a first gate structure over the first fin structure;
forming a first source/drain opening in the first fin structure adjacent to the first gate structure, the first source/drain opening exposing first sidewalls of the layers of the first semiconductor material and first sidewalls of the layers of the second semiconductor material;
forming a first dielectric structure in a lower portion of the first source/drain opening, the first dielectric structure contacting a first subset of the layers of the second semiconductor material;
forming a first source/drain region in an upper portion of the first source/drain opening and over the first dielectric structure, the first source/drain region contacting a second subset of the layers of the second semiconductor material different from the first subset of the layers of the second semiconductor material;
after forming the first source/drain region, removing the first gate structure to expose first portions of the first semiconductor material and first portions of the second semiconductor material;
selectively removing the first portions of the first semiconductor material, wherein after selectively removing the first portions of the first semiconductor material, the first portions of the second semiconductor material remain and form first nanostructures; and
forming a first replacement gate structure around the first nanostructures.

2. The method of claim 1, wherein forming the first NSFET device further comprises, after forming the first replacement gate structure, forming a first interconnect structure over the first replacement gate structure and the first source/drain region.

3. The method of claim 2, further comprising bonding the first interconnect structure to a second interconnect structure of a second NSFET device through direct dielectric-to-dielectric bonding and direct metal-to-metal bonding, wherein the second NSFET device is pre-formed before the bonding and comprises:
a second fin;
second nanostructures over the second fin;
a second gate structure around the second nanostructures;
a second source/drain region adjacent to the second gate structure and contacting at least some of the second nanostructures; and
the second interconnect structure over the second gate structure and the second source/drain region.

4. The method of claim 3, wherein the second NSFET device further comprises a second dielectric structure between the second source/drain region and the second fin, wherein the second dielectric structure contacts a first subset of the second nanostructures, and the second source/drain region contacts a second subset of the second nanostructures.

5. The method of claim 4, wherein a total number of the first nanostructures of the first NSFET device is equal to a total number of the second nanostructures of the second NSFET device, wherein the first source/drain region is in contact with a first number of nanostructures in the first nanostructures, and the second source/drain region is in contact with a second number of nanostructures in the second nanostructures, wherein the second number is different from the first number.

6. The method of claim 3, wherein the second source/drain region contacts all of the second nanostructures.

7. The method of claim 3, wherein the forming the first source/drain region comprises doping the first source/drain region with a first dopant of a first doping type, wherein the second source/drain region comprises a second dopant of a second doping type different from the first doping type.

8. The method of claim 1, wherein forming the first NSFET device further comprises, after forming the first source/drain opening and before forming the first dielectric structure:
replacing end portions of the layers of the first semiconductor material exposed to the first source/drain opening with first inner spacers, wherein the first dielectric structure and the first source/drain region are formed to contact the first inner spacers, wherein an interface between the first source/drain region and the first dielectric structure is disposed between an upper surface of a first one of the first inner spacers and a lower surface of the first one of the first inner spacers.

9. The method of claim 1, wherein forming the first NSFET device further comprises, before removing the first gate structure:
forming a second source/drain opening in the first fin structure adjacent to the first gate structure, wherein the second source/drain opening is at an opposite side of the first gate structure from the first source/drain opening, wherein the second source/drain opening exposes second sidewalls of the layers of the first semiconductor material and second sidewalls of the layers of the second semiconductor material; and
forming a second source/drain region in the second source/drain opening, the second source/drain region contacting the layers of the second semiconductor material.

10. The method of claim 9, wherein the first source/drain opening and the second source/drain opening are formed before the first dielectric structure is formed in the first source/drain opening, wherein forming the first dielectric structure comprises:
filling the first source/drain opening and the second source/drain opening with a dielectric material;
removing the dielectric material from an upper surface of the first gate structure; and
after the removing, performing a plurality of etching processes using different etching masks to remove the dielectric material from the second source/drain opening and from the upper portion of the first source/drain opening, wherein after performing the plurality of etching processes, a portion of the dielectric material remains in the lower portion of the first source/drain opening and forms the first dielectric structure.

11. A method of forming a complementary field-effect transistor (CFET) device, the method comprising:
forming a first nanostructure field-effect transistor (NSFET) device, comprising:
forming a first fin structure protruding above a first substrate, the first fin structure comprising a first fin and a first layer stack over the first fin, wherein the first layer stack comprises layers of a first semiconductor material interleaved with layers of a second semiconductor material;
forming a first gate structure over the first fin structure, the first gate structure overlying first portions of the first semiconductor material and first portions of the second semiconductor material;
forming a first source/drain opening in the first fin structure and at a first side of the first gate structure, the first source/drain opening exposing the first semiconductor material and the second semiconductor material;
forming a first dielectric structure in the first source/drain opening, the first dielectric structure partially filling the first source/drain opening and contacting a first subset of the layers of the second semiconductor material;
forming a first source/drain region in the first source/drain opening and over the first dielectric structure, the first source/drain region contacting a second subset of the layers of the second semiconductor material disposed over the first subset of the layers of the second semiconductor material;
after forming the first source/drain region, removing the first gate structure and selectively removing the first portions of the first semiconductor material, wherein after the selectively removing, the first portions of the second semiconductor material remain and form first nanostructures;
forming a first replacement gate structure around the first nanostructures; and
forming a first interconnect structure over the first replacement gate structure and the first source/drain region; and
bonding the first interconnect structure of the first NSFET device to a second interconnect structure of a second NSFET device, wherein the second NSFET device comprises:
a second fin;
second nanostructures over the second fin;
a second gate structure around the second nanostructures;
a second source/drain region adjacent to the second gate structure and contacting at least some of the second nanostructures; and
the second interconnect structure over the second source/drain region and the second gate structure.

12. The method of claim 11, wherein the second nanostructures, the second gate structure, the second source/drain region, and the second interconnect structure of the second NSFET device are pre-formed before the bonding.

13. The method of claim 12, wherein the first interconnect structure of the first NSFET device is bonded to the second interconnect structure of the second NSFET device through direct dielectric-to-dielectric bonding and direct metal-to-metal bonding without using a solder material.

14. The method of claim 11, wherein forming the first NSFET device further comprises, before removing the first gate structure:
forming a second source/drain opening in the first fin structure and at a second opposing side of the first gate structure, wherein the second source/drain opening exposes the first semiconductor material and the second semiconductor material; and
forming a third source/drain region in the second source/drain opening, the third source/drain region contacting the layers of the second semiconductor material.

15. The method of claim 11, wherein the second NSFET device further comprises a second dielectric structure between the second fin and the second source/drain region, wherein the second dielectric structure contacts a first subset of the second nanostructures, and the second source/drain region contacts a second subset of the second nanostructures.

16. The method of claim 15, wherein a first number of the layers of the second semiconductor material is in the first subset of the layers of the second semiconductor material, wherein a second number of the second nanostructures is in the first subset of the second nanostructures.

17. The method of claim 16, wherein the first number is different from the second number.

18. A complementary field-effect transistor (CFET) device comprising:
a first nanostructure field-effect transistor (NSFET) device comprising:
a first fin;
first nanostructures stacked vertically over the first fin;
a first gate structure around the first nanostructures;
a first source/drain region adjacent to the first gate structure, the first source/drain region contacting a first subset of the first nanostructures;
a first dielectric structure between the first source/drain region and the first fin, the first dielectric structure contacting a second subset of the first nanostructures; and
a first interconnect structure over and electrically coupled to the first source/drain region; and
a second NSFET device comprising:
a second fin;
second nanostructures vertically stacked over the second fin;
a second gate structure around the second nanostructures;
a second source/drain region adjacent to the second gate structure, the second source/drain region contacting at least some of the second nanostructures; and
a second interconnect structure over and electrically coupled to the second source/drain region, wherein the second interconnect structure is bonded to the first interconnect structure such that the first interconnect structure is disposed between the first source/drain region and the second interconnect structure.

19. The CFET device of claim 18, wherein the first source/drain region is of a first conductivity type, and the second source/drain region is of a second conductivity type different from the first conductivity type.

20. The CFET device of claim 18, wherein the second NSFET device further comprises a second dielectric structure between the second fin and the second source/drain region, wherein the second source/drain region contacts a first subset of the second nanostructures, and the second dielectric structure contacts a second subset of the second nanostructures.
